(19) United States
(12) Patent Application Publication
(10) Pub. No.: US 2010/0176388 A1
(43) Pub. Date: Jul. 15, 2010

(54) THIN FILM TRANSISTOR, METHOD OF MANUFACTURING THE SAME AND FLAT PANEL DISPLAY DEVICE HAVING THE SAME

(75) Inventors: Jae-Heung Ha, Yongin-city (KR); Jong-Hyuk Lee, Yongin-city (KR); Young-Woo Song, Yongin-city (KR); Chaungi Choi, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-city (KR)

(21) Appl. No.: 12/685,207

(22) Filed: Jan. 11, 2010

(30) Foreign Application Priority Data
Jan. 12, 2009 (KR) 10-2009-0002240

(51) Int. Cl. H01L 51/52; H01L 29/786; H01L 21/34

(52) U.S. Cl. 257/40; 257/43; 438/104; 257/E29.296; 257/E51.022; 257/E21.46

(57) ABSTRACT

A thin film transistor which has a compound semiconductor including oxygen as an activation layer, a method of manufacturing the thin film transistor, and a flat panel display device having the thin film transistor, of which the thin film transistor comprises: a gate electrode formed on a substrate; an activation layer formed on the gate electrode, insulated from the gate electrode by a gate insulating film, and formed of a compound semiconductor including oxygen; a passivation layer formed on the activation layer; and source and drain electrodes formed to contact the activation layer, wherein the passivation layer includes titanium oxide (TiOₓ) or titanium oxynitride (TiOₓN_{y}).

### CROSS-REFERENCE TO RELATED APPLICATIONS

This application claims the benefit of Korean Patent Application No. 10-2009-0002240, filed on Jan. 12, 2009, in the Korean Intellectual Property Office, the content of which is incorporated herein by reference.

### BACKGROUND OF THE INVENTION

1. Field of the Invention

Aspects of the present invention relate to a thin film transistor, a method of manufacturing the same, and a flat panel display device having the same.

2. Description of the Related Art

A thin film transistor generally includes an activation layer having a channel region, a source region, and a drain region, and a gate electrode, which is formed on an upper or lower portion of the channel region and is electrically insulated from the activation layer by a gate insulating film.

The activation layer of the thin film transistor formed as described above is generally formed of semiconductor material, such as amorphous silicon or poly-silicon (i.e., polycrystalline silicon). However, if the activation layer is formed of the amorphous silicon, it is difficult to implement a high speed driving circuit due to low electron/hole mobility therein; and if the activation layer is formed of the poly-silicon, a separate compensation circuit should be added due to an uneven threshold voltage, despite high electron/hole mobility. Also, a conventional method of manufacturing the thin film transistor using a low temperature poly-silicon (LTPS) includes an expensive process, such as a laser annealing, etc., and is difficult to control the properties of the resultant transistors.

Compound semiconductors have recently been suggested as an activation layer in order to solve such problems. Japanese Laid-Open Patent Publication No. 2004-273614 discloses a thin film transistor having an activation layer form mainly of zinc oxide (ZnO) or a compound semiconductor having zinc oxide (ZnO).

The compound semiconductor having zinc oxide (ZnO) as a main ingredient is evaluated as an amorphous, stable material. If such a compound semiconductor is used as an activation layer, the compound semiconductor has various advantages in that the thin film transistor may be manufactured at a low temperature below 350° C. using existing processing equipment and an ion implantation process may be omitted.

However, if the compound semiconductor is used, when forming a thin film on an upper portion of the activation layer or etching the formed thin film, damage due to plasma is generated such that a change in an electrical property is generated. The negative changes in electrical properties may include an increase in carriers due to a bombardment effect and a radiation effect, etc. Because of the deterioration of the electrical properties of the compound semiconductor, a change in threshold voltage of the thin film transistor, etc., and a degree of dispersion of the electrical properties within a substrate deteriorate.

In a thin film transistor having an activation layer formed of poly-silicon, a passivation layer is generally formed of silicon oxide SiO₂, silicon nitride SiNₓ or aluminum oxide Al₂O₃. However, in a thin film transistor having an activation layer formed of a compound semiconductor including oxygen, if a passivation layer is formed of silicon oxide SiO₂, silicon nitride SiNₓ or aluminum oxide Al₂O₃, it causes deterioration in electrical properties. The deterioration in the electrical properties is inferred to be the result of damage of the activation layer generated by plasma during a deposition process. If the damage due to plasma is generated, carrier concentration of the activation layer may be increased because of oxygen deficiency, off current may be increased because of such an excess carrier, and an S-factor property may deteriorate.

### SUMMARY OF THE INVENTION

Aspects of the present invention provide a thin film transistor which can prevent the deterioration of electrical properties and the degree of dispersion thereof due to damage of an activation layer, a method of manufacturing the thin film transistor, and a flat panel display device having the thin film transistor. Aspects of the present invention provide a thin film transistor which can be applied to a large substrate in order to make a large display device, a method of manufacturing the thin film transistor, and a flat panel display device having the thin film transistor.

According to aspects of the present invention, there is provided a thin film transistor including: a gate electrode formed on a substrate; an activation layer formed on the gate electrode, insulated from the gate electrode by a gate insulating film, and formed of a compound semiconductor including oxygen; a passivation layer formed on the activation layer; and source and drain electrodes formed to contact the activation layer, wherein the passivation layer includes a titanium oxide (TiOₓ).

According to another aspect of the present invention, there is provided a method of manufacturing a thin film transistor, including: forming a gate electrode on a substrate; forming a gate insulating film to cover the gate electrode: forming an activation layer formed of a compound semiconductor including oxygen on the gate insulating film; forming a passivation layer that includes titanium oxide on the activation layer; and forming source and drain electrodes to contact the activation layer.

According to another aspect of the present invention, there is provided a flat panel display device, including: a plurality of pixels, each having a first electrode, defined by a plurality of first conductive lines and second conductive lines formed on a first substrate; thin film transistors respectively connected to the first electrodes of the pixels to control signals supplied to each pixel from the first conductive lines and the second conductive lines formed on the first substrate; a second substrate on which a second electrode is formed, the second substrate being disposed to face the first substrate; and a liquid crystal layer disposed between the first electrode and the second electrode, wherein the thin film transistor includes: a gate electrode formed on the first substrate; an activation layer formed on the gate electrode, insulated from the gate electrode by a gate insulating film, and formed of a compound semiconductor including oxygen; a passivation layer formed on the activation layer; and source and drain electrodes formed to contact the activation layer, and the passivation layer includes titanium oxide (TiOₓ).

According to another aspect of the present invention, there is provided a flat panel display device, including: a first substrate on which an organic light emitting device is formed, the organic light emitting device including of a first electrode, a second electrode, and an organic thin film layer disposed between the first electrode and the second electrode; a thin film transistor disposed on the first substrate and connected to the first electrode of the organic light emitting device to control the operation of the organic light emitting device; and a second substrate disposed to face the first substrate, wherein the thin film transistor includes: a gate electrode formed on the first substrate; an activation layer formed on the gate electrode, insulated from the gate electrode by a gate insulating film, and formed of a compound semiconductor including oxygen; a passivation layer formed on the activation layer; and source and drain electrodes formed to contact the activation layer, and the passivation layer includes titanium oxide (TiOₓ).

The thin film transistor according to aspects of the present invention has an activation layer formed of the compound semiconductor including oxygen, and an passivation layer, which includes a titanium oxide, on the activation layer. The passivation layer prevents the channel region from being contaminated or damaged, making it possible to prevent the electrical property of the thin film transistor from being deteriorated due to the damage of the activation layer, to improve the degree of dispersion of the threshold voltage within the substrate, and to make a process procedure easy since it can be used as an etch stop layer during the process forming the source and drain electrodes. Also, the passivation layer that includes the titanium oxide can be formed using a direct current (DC) reactive sputtering method using a metal target so that it can be applied to a large area substrate, making it possible to make a large display device with ease.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A and 1B are cross-sectional views showing a thin film transistor according to an embodiment of the present invention;

FIGS. 2A to 2D are cross-sectional views showing a method of manufacturing a thin film transistor according to aspects of the present invention;

FIGS. 3A to 3C are graphs showing electrical properties of a thin film transistor measured before a passivation layer is formed and after the passivation layer is formed;

FIG. 4 is a plan view showing a flat panel display device including a thin film transistor according to aspects of the present invention;

FIGS. 5A and 5B are a plan view and a cross-sectional view showing a flat panel display device including a thin film transistor according to aspects of the present invention; and

FIG. 6 is a cross-sectional view showing the organic light emitting device of FIG. 5A.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on,” “formed on,” or “disposed on” another element, it can be directly on another element or be indirectly on the element with one or more intervening elements disposed therebetween. Also, when an element is referred to as being “connected to” another element, it can be directly connected to the element or be indirectly connected to the element with one or more intervening elements disposed therebetween.

Aspects of the present invention provide a thin film transistor that can prevent the deterioration of electrical properties and a degree of dispersion thereof due to damage of an activation layer and can be applied to a large substrate to make a large display device, and a method of manufacturing the same.

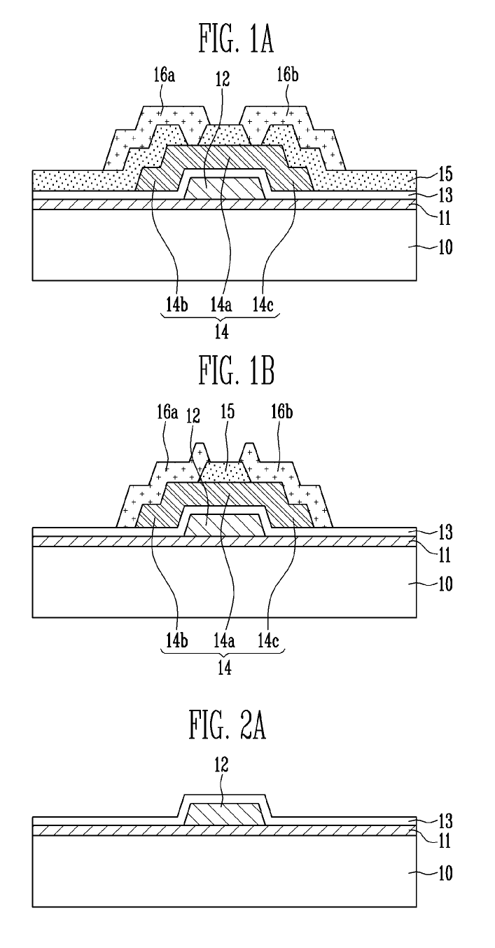

FIGS. 1A and 1B are cross-sectional views showing a thin film transistor according to an embodiment of the present invention. Referring to FIG. 1A, a buffer layer 11 is formed on a substrate 10 and a gate electrode 12 is formed on the buffer layer 11. A gate insulating film 13 is formed on the substrate to cover at least the gate electrode 12, and an activation layer 14 formed of a compound semiconductor is formed on the gate insulating film 13. The activation layer 14 provides a channel region 14a, a source region 14b, and a drain region 14c, wherein the channel region 14a overlaps the gate electrode 12. Also, a passivation layer 15 is formed on the activation layer 14 in at least the channel region 14a, and source and drain electrodes 16a and 16b contact the activation layer 14 in the source and drain regions 14b and 14c.

FIG. 1A shows a structure where the passivation layer 15 is formed on the activation layer 14 in the channel region 14a, and the passivation layer 15 is formed on the entirety of the upper portion of the substrate 10 including the activation layer 14 such that the source and drain electrodes 16a and 16b contact the activation layer 14 in the source and drain regions 14b and 14c through contact holes formed on the passivation layer 15. In contrast, FIG. 1B shows a structure where the passivation layer 15 is formed only on the activation layer 14 in the channel region 14a such that the source and drain electrodes 16a and 16b contact the activation layer 14 in the source and drain regions 14b and 14c directly.

The activation layer 14 is formed of a compound semiconductor including oxygen, for example, zinc oxide (ZnO), wherein the compound semiconductor may be doped with at least one ion selected from a group consisting of gallium (Ga), indium (In), tin (Sn), zirconium (Zr), hafnium (Hf), and vanadium (V). Also, the passivation layer 15 is formed of titanium oxide (TiOx) or titanium oxynitride (TiOxNy).

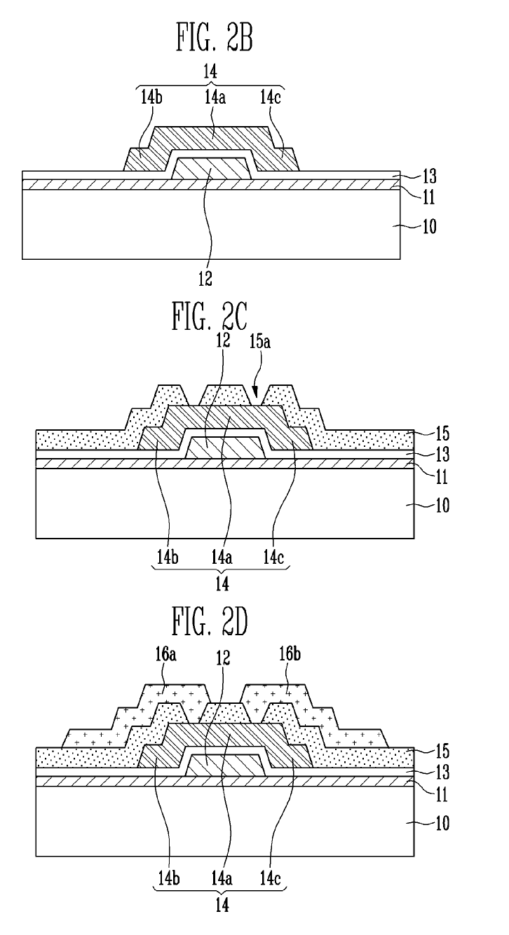

Now, aspects of the present invention will be described in more detail through a method of manufacturing a thin film transistor. FIGS. 2A to 2D are cross-sectional views showing a method of manufacturing a thin film transistor according to aspects of the present invention. Referring to FIG. 2A, after a buffer layer 11 is formed on a substrate 10, a gate electrode 12 is formed on the buffer layer and a gate insulating film 13 is formed on the substrate to cover at least the gate electrode 12. As the substrate 10, a semiconductor substrate, such as silicon Si, etc., an insulating substrate, such as glass or plastic, etc., or a metal substrate is used. The gate electrode 12 may be formed of a metal, such as Al, Cr, and MoW, etc., or a conductive polymer, etc., and the gate insulating film 13 may be formed of insulating material, such as SiO₂, SiNₓ, and Ga₂O₃, etc.

Referring to FIG. 2B, an activation layer 14 formed of a compound semiconductor is formed on the gate insulating film 13. The activation layer 14 includes a channel region 14a, a source region 14b, and a drain region 14c, wherein the channel region 14a overlaps the gate electrode 12. The activation layer 14 is formed of a compound semiconductor including oxygen, for example, zinc oxide (ZnO), wherein the compound semiconductor may be doped with at least one ion selected from a group consisting of gallium (Ga), indium (In), tin (Sn), zirconium (Zr), hafnium (Hf), and vanadium (V). For example, the compound semiconductor may be ZnO, ZnGaO, ZnInO, ZnSnO, and GaInZnO, etc.

Referring to FIG. 2C, after a passivation layer 15 that includes titanium oxide (TiOₓ) is formed on the substrate over the activation layer 14, the passivation layer 15 is patterned to form contact holes 15a so that the source and drain regions 14b and 14c of the activation layer 14 are exposed. During the patterning of the passivation layer, the passivation layer 15 may be patterned to leave behind only on the upper portion of the activation layer 14 in the channel region 14a, as shown in FIG. 1B.

The passivation layer 15 that includes the titanium oxide (TiOₓ) protects the activation layer 14 from moisture or oxygen, and prevents the activation layer 14 from being contaminated or damaged. Since the titanium oxide (TiOₓ) (x=0.3˜3.0) and the titanium oxynitride (TiOₓN_{y}) (x=0.3˜3.0; y=0.3˜5.0) that is used as the passivation layer 15, can be deposited using a direct current (DC) reactive sputtering method using a metal target, it can be applied to a large area substrate, making it possible to easily make the display device large. For example, the titanium oxide (TiOₓ) or the titanium oxynitride (TiOₓN_{y}) can be deposited on a large area substrate while controlling the amount of oxygen (O) and nitrogen (N) using the DC reactive sputtering method using a titanium (Ti) target.

For reference, an inorganic material, such as oxide or nitride, is commonly deposited using a RF sputtering method or a chemical vapor deposition method. However, the RF sputtering method has disadvantages in that a deposition rate is low and the deposition is not easily performed for a large substrate. The chemical vapor deposition method also has disadvantages in that the electrical properties of the compound semiconductor are deteriorated since oxygen is diffused during the deposition process. In contrast, the DC reactive sputtering method can deposit a thin film stably on a large area substrate. However, since gallium (Ga) or aluminum (Al), etc., has a low melting point or generates a serious arc discharge, a proper metal target should be selected. Titanium (Ti) may be deposited stably on a large area substrate of 730 mm×920 mm, i.e., a fourth-generation substrate, or more using the DC reactive sputtering method. Therefore, if the amount (partial pressure) of oxygen (O) and nitrogen (N) is properly controlled during the deposition process, titanium oxide (TiOₓ) or titanium oxynitride (TiOₓN_{y}) having a desired layer can be deposited.

Referring to FIG. 2D, after a conductive layer formed of Mo, MoW, Al, AlNd, and AlLiLa, etc., is formed on the passivation layer 15 so that the contact holes 15a are filled and the conductive layer contacts the source and drain regions 14b and 14c of the activation layer 14, the conductive layer is patterned to form source and drain electrodes 16a and 16b connected to the source and drain regions 14b and 14c through the contact holes 15a. The passivation layer 15 may be used as an etch stop layer during the patterning process of the conductive layer thereby making it possible to make the etching process easy, to protect the activation layer 14 in the channel region 14a, and to prevent the activation layer 14 from being contaminated by an organic material, etc., during a subsequent process.

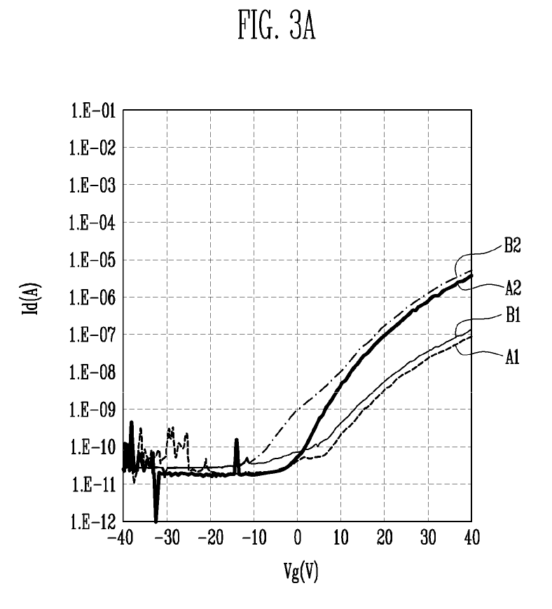

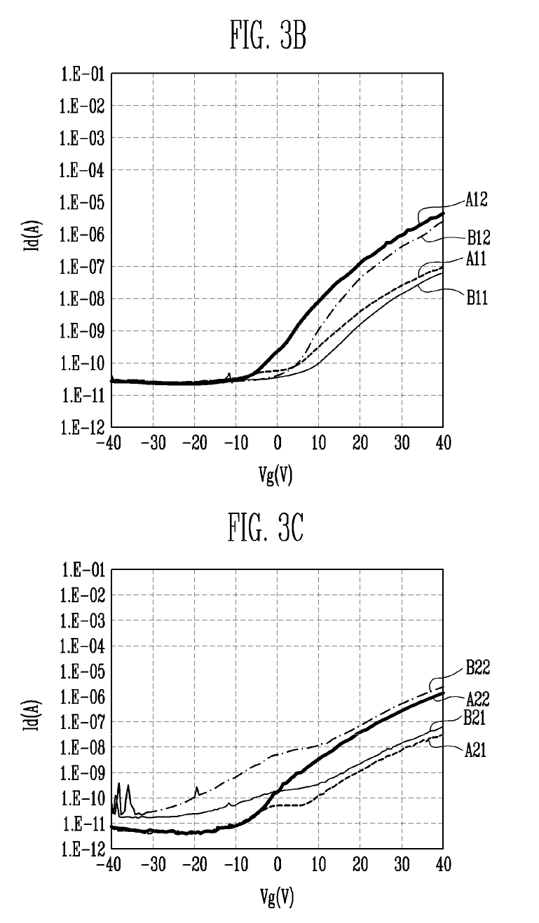

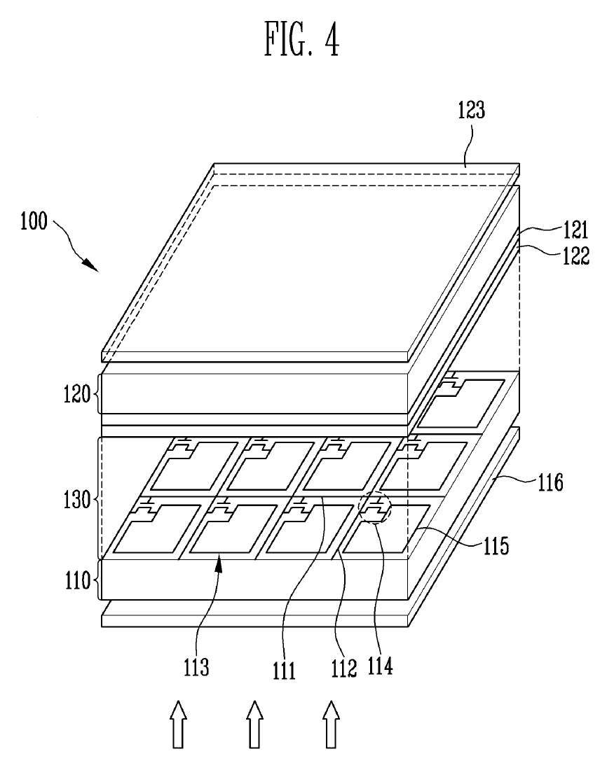

FIGS. 3A to 3C are graphs showing transfer curves in drain current Id according to gate voltage Vg before and after the passivation layer 15 is formed. In FIG. 3A, the partial pressure of oxygen (O₂) was controlled to 15%; in FIG. 3B, the partial pressure of oxygen (O₂) was controlled to 19%; and in FIG. 3C, the partial pressure of nitrogen (N₂) was controlled to 13%. In FIGS. 3A to 3C, lines A1, A11, and A21, and lines A2, A12, and A22 represent measurement results before the passivation layer was formed, measured when voltage Vds between the source and drain electrodes 16a and 16b was in the range of 0.1V and 5.1V; and lines B1, B11, and B21, and lines B2, B12, and B22 represent the measurement results after the passivation layer was formed, measured when voltage Vds between the source and drain electrodes 16a and 16b was in the range of 0.1V and 5.1V.

As shown in FIGS. 3A to 3C, the change in threshold voltage before and after the passivation layer is formed is very small, thereby indicating that the activation layer 14 was not contaminated or damaged by the passivation layer 15.

The thin film transistor according to aspects the present invention as described above can be applied to a flat panel display device. FIG. 4 is a perspective view showing a flat panel display device having a thin film transistor according to aspects of the present invention, wherein the flat panel display device will be schematically explained based on a display panel 100, which displays an image.

The display panel 100 includes two substrates 110 and 120 disposed to face each other, and a liquid crystal layer 130 disposed between the two substrates 110 and 120, wherein a pixel region 113 is defined by a plurality of gate lines 111 and data lines 112 arranged on the substrate 110 in a matrix. A thin film transistor 114, which controls signals to be supplied to each pixel, and a pixel electrode 115 connected to the thin film transistor 114 are formed on the substrate 110 adjacent to intersections between the gate lines 111 and the data lines 112.

The thin film transistor 114, which has the structure of FIG. 1A or 1B, may also be manufactured according to the manufacturing method according to aspects of the present invention described with reference to FIGS. 2A to 2D.

A color filter 121 and a common electrode 122 are formed on the substrate 120. Polarizing plates 116 and 123 are formed on rear surfaces of the substrates 110 and 120, respectively, i.e., outside or exterior surfaces of the substrates 110 and 120, wherein a backlight (not shown) is disposed on the lower portion of the polarizing plate 116 as a light source.

Meanwhile, a driver IC (not shown), which drives the display panel 100, is mounted in a periphery of a pixel region 113 of the display panel 100. The driver converts electrical signals provided from an external source into scan signals and data signals and supplies such signals to the gate lines 111 and the data lines 112.

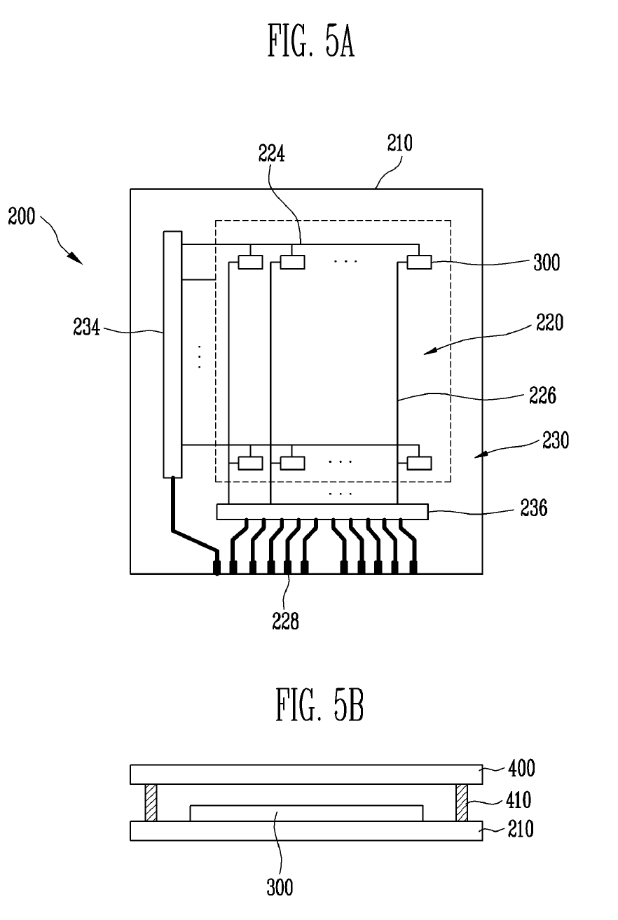

FIGS. 5A and 5B are a plan view and a cross-sectional view showing a flat panel display device having a thin film transistor according to aspects of the present invention, wherein the flat panel display device will be schematically explained based on a display panel 200, which displays an image.

Referring to FIG. 5A, a substrate 210 includes a pixel region 220 and a non-pixel region 230 surrounding the pixel region 220. A plurality of organic light emitting devices 300 coupled between scan lines 224 and data lines 226, arranged in a matrix, are formed on the substrate 210 in the pixel region 220. The scan lines 224 and data lines 226 extend into the pixel region from a scan driver 234 and a data driver 236, respectively. Power supply lines (not shown), which operate the organic light emitting device 300, and the scan driver 234 and the data driver 236, which process the signals provided from an external source to supply the scan and data signals to the scan lines 224 and the data lines 226 are formed on the substrate in the non-pixel region 230.

Referring to FIG. 5B, a sealing substrate 400, which seals the pixel region 220, is disposed on the upper portion of the substrate 210 formed with the organic light emitting device 300, and the sealing substrate 400 is bonded to the substrate 210 by a sealant 410, thereby completing a display panel 200.

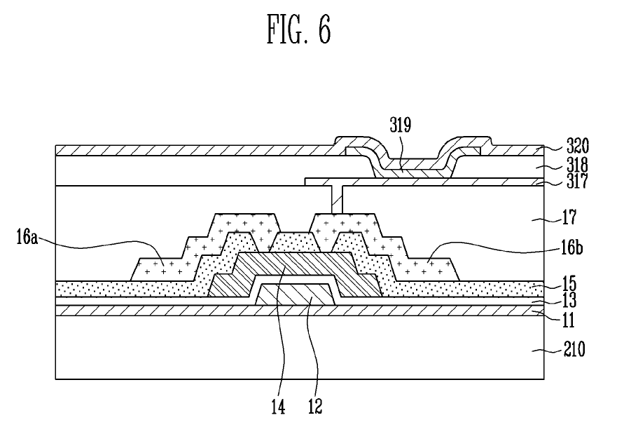

Referring to FIG. 6, an organic light emitting display device including the organic light emitting device 300 includes an anode electrode 317, a cathode electrode 320, and an organic thin film layer 319 formed between the anode electrode 317 and the cathode electrode 320. Although described herein as an anode electrode 317 and a cathode electrode 320, aspects of the present invention are not limited thereto such that the polarities of such electrodes may be reversed. The organic thin film layer 319 is formed having a structure in which a hole transport layer, an organic light emitting layer, and an electron transport layer are stacked, and a hole injection layer and an electron injection layer may further be included. The organic light emitting device 300 may further include a thin film transistor which controls the operation of the organic light emitting device 300 and a capacitor, which maintains signals applied thereto.

The thin film transistor, which has the structure of FIG. 1A or 1B, may be manufactured according to the manufacturing method according to aspects of the present invention with reference to FIGS. 2A to 2D. Although the thin film transistor having the structure shown in FIG. 1A is shown in FIG. 6, aspects of the present invention are not limited thereto such that the structure of the thin film transistor of FIG. 1B be included in the organic light emitting display device of FIG. 6.

The organic light emitting display device that includes the thin film transistor as described above will be described in more detail with reference to FIGS. 5A and 6.

A buffer layer 11 is formed on a substrate 210, and a gate electrode 12 is formed on the buffer layer 11 in a pixel region 220. Scan lines 224 coupled to a gate electrode 12 may be formed in the pixel region 220, and the scan lines 224 extend from the scan driver 234 into the pixel region 220; and pads 228 that receive signals from an external source may be formed in a non-pixel region 230.

An activation layer 14 is formed on the substrate over the gate electrode 14, being insulated from the gate electrode 12 by a gate insulating film 13 and provides a channel region 14a, a source region 14b, and a drain region 14c (shown in FIG. 1A).

A passivation layer 15 is formed on the activation layer 14, wherein contact holes are formed in the passivation layer 15 so that source and drain regions 14b and 14c of the activation layer 14 are exposed. On the passivation layer 15, source and drain electrodes 16a and 16b are formed to contact the source and drain regions 14b and 14c through the contact holes. The data lines 226 connected to the source and drain electrodes 16a and 16b are formed in the pixel region 220, and the data lines 226 extend from the data driver 236 into the pixel region 220; and the pads 228 that receive signals from an external source are formed in the non-pixel region 230. Although shown in FIG. 6 as the passivation layer 15 of FIG. 1A, aspects of the present invention are not limited thereto such that the passivation layer 15 of FIG. 1B may be included therein.

A planarization layer 17 is formed on the source and drain electrodes 16a and 16b, and a via hole is formed on the planarization layer 17 so that one of the source and drain electrodes 16a or 16b is exposed. The anode electrode 317 connected to the source or drain electrode 16a or 16b through the via hole is formed.

A pixel definition film 318 is formed on the planarization layer 317 such that at least a portion (i.e., light-emitting region) of the anode electrode 317 is exposed, an organic thin film layer 319 is formed on the exposed anode electrode 317, and a cathode electrode 320 is formed on the pixel definition film 318 including the organic thin film layer 319.

Referring back to FIG. 5B, the sealing substrate 400, which seals the pixel region 220 is disposed on the upper portion of the substrate 210 formed with the organic light emitting device 300, and the sealing substrate 400 is bonded to the substrate 210 by a sealant 410, thereby completing a display panel 200.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film transistor, comprising:
a substrate;
a gate electrode formed on the substrate;
an activation layer formed on the gate electrode, insulated from the gate electrode by a gate insulating film, and formed of a compound semiconductor including oxygen;
a passivation layer formed on the activation layer; and
source and drain electrodes formed to contact the activation layer,
wherein the passivation layer comprises a titanium oxide (TiOₓ).

2. The thin film transistor of claim 1, wherein the passivation layer is formed to cover the activation layer, and the source and drain electrodes contact the activation layer through contact holes formed in the passivation layer.

3. The thin film transistor of claim 1, wherein the compound semiconductor comprises zinc oxide (ZnO).

4. The thin film transistor of claim 3, wherein the compound semiconductor is doped with at least one ion selected from a group consisting of gallium (Ga), indium (In), tin (Sn), zirconium (Zr), hafnium (Hf) and vanadium (V).

5. The thin film transistor of claim 1, wherein the TiOₓ is titanium oxynitride (TiOₓN_{y}).

6. The thin film transistor of claim 1, further comprising:
a buffer layer formed between the substrate and the gate electrode.

7. The thin film transistor of claim 1, wherein the activation layer comprises:
a channel region, a source region, and a drain region,
wherein the passivation layer is formed to cover only the channel region of the activation layer and the source and drain electrodes are respectively connected to the source and drain regions of the activation layer.

8. The thin film transistor of claim 7, wherein the source and drain electrodes are disposed directly on the source and drain regions of the activation layer, respectively.

9. The thin film transistor of claim 1, wherein the compound semiconductor comprises at least one of ZnO, ZnGaO, ZnInO, ZnSnO, and GaInZnO.

10. The thin film transistor for claim 1, wherein x of TiOₓ is in a range of about 0.3 to about 3.0.

11. The thin film transistor of claim 5, wherein x of TiOₓN_{y} is in a range of about 0.3 to about 3.0, and y of TiOₓN_{y} is in a range of about 0.3 to about 5.0.

12. A method of manufacturing a thin film transistor, comprising:
forming a gate electrode on a substrate;
forming a gate insulating film on of the substrate to cover the gate electrode:
forming an activation layer on the gate insulating film, the activation layer being formed of a compound semiconductor including oxygen;
forming a passivation layer that comprises a titanium oxide (TiOₓ) on the activation layer; and
forming source and drain electrodes to contact the activation layer.

13. The method of manufacturing the thin film transistor of claim 12, wherein the forming the passivation layer comprises:
forming the passivation layer on the activation layer; and
forming contact holes in the passivation layer.

14. The method of manufacturing the thin film transistor of claim 13, wherein the forming the source and drain electrodes comprises:
forming a conductive layer on the passivation layer such that the contact holes are filled and the conductive layer contacts the activation layer via the contact holes; and
patterning the conductive layer to form the source and drain electrodes.

15. The method of manufacturing the thin film transistor of claim 12, wherein the compound semiconductor includes zinc oxide (ZnO).

16. The method of manufacturing the thin film transistor of claim 15, wherein the compound semiconductor is doped with at least one ion selected from a group consisting of gallium (Ga), indium (In), tin (Sn), zirconium (Zr), hafnium (Hf) and vanadium (V).

17. The method of manufacturing the thin film transistor of claim 12, wherein the TiOₓ is titanium oxynitride (TiOₓN_{y}).

18. The method of manufacturing the thin film transistor of claim 12, wherein the passivation layer is formed using a direct current (DC) reactive sputtering method.

19. The method of manufacturing the thin film transistor of claim 12, wherein the forming the source and drain electrodes comprises using the passivation layer as an etch stop layer.

20. The method of manufacturing the thin film transistor of claim 12, further comprising:
forming a buffer layer on the substrate before the forming of the gate electrode.

21. The method of manufacturing the thin film transistor of claim 12, wherein the activation layer comprises: a channel, a source, and a drain region, and the method further comprises:
patterning the passivation layer to remain only on the channel region of the activation layer.

22. A flat panel display device, comprising:
a first substrate on which a plurality of pixels, each having a first electrode, are defined by a plurality of first conductive lines and second conductive lines;
thin film transistors respectively connected to the first electrodes of the pixels to control signals supplied to the respective pixels from the first conductive lines and the second conductive lines formed on the first substrate;
a second substrate on which a second electrode is formed, the second substrate being disposed to face the first substrate; and
a liquid crystal layer disposed between the first electrode and the second electrode,
wherein each thin film transistor comprises:
a gate electrode formed on the first substrate;
an activation layer formed on the gate electrode, insulated from the gate electrode by a gate insulating film, and formed of a compound semiconductor including oxygen;
a passivation layer formed on the activation layer; and
source and drain electrodes formed to contact the activation layer,
wherein the passivation layer comprises a titanium oxide (TiOₓ).

23. The flat panel display device of claim 22, wherein the passivation layer is formed to cover the activation layer, and the source and drain electrodes contact the activation layer through contact holes formed in the passivation layer.

24. The flat panel display device of claim 22, wherein the compound semiconductor comprises zinc oxide (ZnO).

25. The flat panel display device of claim 24, wherein the compound semiconductor is doped with at least one ion selected from a group consisting of gallium (Ga), indium (In), tin (Sn), zirconium (Zr), hafnium (Hf) and vanadium (V).

26. The flat panel display device of claim 22, wherein the TiOₓ is titanium oxynitride (TiOₓN_{y}).

27. A flat panel display device, comprising:
a first substrate on which an organic light emitting device is formed, the organic light emitting device including a first electrode, a second electrode, and an organic thin film layer disposed between the first electrode and the second electrode;
a thin film transistor disposed on the first substrate and connected to the first electrode of the organic light emitting device to control the operation of the organic light emitting device; and
a second substrate disposed to face the first substrate,
wherein the thin film transistor comprises:
a gate electrode formed on the first substrate;
an activation layer formed on the gate electrode and insulated from the gate electrode by a gate insulating film, and formed of a compound semiconductor including oxygen;
a passivation layer formed on the activation layer; and
source and drain electrodes formed to contact the activation layer,
wherein the passivation layer comprises a titanium oxide (TiOₓ).

28. The flat panel display device of claim 27, wherein the passivation layer is formed to cover the activation layer, and the source and drain electrodes contact the activation layer through contact holes formed in the passivation layer.

29. The flat panel display device of claim 27, wherein the compound semiconductor includes zinc oxide (ZnO).

30. The flat panel display device of claim 29, wherein the compound semiconductor is doped with at least one ion selected from a group consisting of gallium (Ga), indium (In), tin (Sn), zirconium (Zr), hafnium (Hf) and vanadium (V).

31. The flat panel display device of claim 27, wherein the TiOₓ is titanium oxynitride (TiOₓN_{y}).
